(19) United States
(12) Patent Application Publication
(10) Pub. No.: US 2025/0389994 A1
(43) Pub. Date: Dec. 25, 2025

(54) ARRAY SUBSTRATE, MANUFACTURING METHOD THEREOF, AND DISPLAY PANEL

(71) Applicant: TCL CHINA STAR OPTOELECTRONIC TECHNOLOGY CO., LTD., Shenzhen, Guangdong (CN)

(72) Inventors: Sen XU, Shenzhen, Guangdong (CN); Bangqing XIAO, Shenzhen, Guangdong (CN)

(21) Appl. No.: 17/438,482

(22) PCT Filed: Jun. 18, 2021
(86) PCT No.: PCT/CN2021/100792

§ 371 Date: Apr. 23, 2025

(30) Foreign Application Priority Data
Jan. 21, 2021 (CN) 202110079480.5

(51) Int. Cl. G02F 1/1362; G02F 1/1368; H10D 86/40; H10D 86/60

(52) U.S. Cl. CPC G02F 1/136295; G02F 1/1368; H10D 86/441; H10D 86/60

(57) ABSTRACT

An array substrate, a manufacturing method thereof, and a display panel are provided. The array substrate includes a substrate. A plurality of sub-pixels are disposed on the substrate. Each of the sub-pixels includes a pixel electrode, and the pixel electrode includes a first stem electrode disposed along a first direction. A plurality of first data lines are disposed on the substrate. Each of the data lines is connected to a group of the sub-pixels extending along the first direction. A plurality of first scan lines extending along the first direction are disposed on the substrate.

### FIELD

The present disclosure relates to a field of display device technologies, and more particularly, to an array substrate, a manufacturing method thereof, and a display panel.

### BACKGROUND

Nowadays, with gradual development of liquid crystal displays (LCDs), products are developed toward a direction of high resolution, narrow frames, and a thin and light body. Consequently, ultra-narrow border technologies are released. A conventional ultra-narrow border technology having three narrow edges and one wide edge has a gate driver in source chip on film (GCOF) design. In such design, a driving signal of a horizontal scan line (a scan line perpendicular to a line) is outputted from a COF on a side of a source. Because a gate on array (GOA) technology is not applied to such design, a width of two borders is reduced.

The driving signal of the horizontal scan line (the scan line perpendicular to a line) in conventional GCOF designs passes between two sub-pixels. A half gate double data (HG2D) driving method or a one gate one data (1G1D) driving method may be applied to such design. Wherein, 1G1D means in a display area of a display panel, sub-pixels in a same row are electrically connected to a same horizontal scan line, and sub-pixels in a same column are electrically connected to a same data line.

In conventional 1G1D designs, as shown in FIG. 1, each of sub-pixels of each column is provided with a pixel electrode 130. A side of the pixel electrode 130 is connected to a first data line 110, and each sub-pixel of each column is spaced apart from a second data line 120. Wherein, the second data line 120 is connected to sub-pixels adjacent to the second data line by a pixel electrode. A vertical signal line 140 of a scan line of each sub-pixel is disposed on a side of the pixel electrode 130 and is spaced apart from the first data line 110 or the second data line 120. Because the signal line is commonly made of metal, an area of the pixel electrode is limited by designs of conventional vertical signal line, which is not beneficial for increasing transmittance of liquid crystal display (LCD) panels.

### SUMMARY

### Technical issue

The present disclosure provides an array substrate, a manufacturing method thereof, and a display panel to solve a following issue: an aperture ratio of conventional array substrates is low.

### SOLUTION TO ISSUE

### Technical solution

In a first aspect, the present disclosure provides an array substrate, including a substrate;

a plurality of sub-pixels are arranged in an array manner on the substrate, each of the sub-pixels comprises a pixel electrode, and the pixel electrode comprises a first stem electrode disposed along a first direction;

a plurality of first data lines extend along the first direction on the substrate, each of the first data lines is connected to a group of the sub-pixels, and the group of the sub-pixels extends along the first direction; and

a plurality of first scan lines extend along the first direction on the substrate, an orthographic projection of one of the first scan lines overlaps with an orthographic projection of the first stem electrode on the substrate.

In the array substrate of the present disclosure, the substrate further comprises:
a plurality of second data lines extending along the first direction and spaced apart from each other along a second direction on the substrate, wherein each column of the sub-pixels is disposed between one of the first data lines and one of the second data lines which are adjacent to each other, distances between the pixel electrode of each of the sub-pixels and two of the first data lines adjacent to the pixel electrode of each of the sub-pixels are equal, and the first direction and the second direction crisscross each other.

In the array substrate of the present disclosure, the substrate further comprises:
a plurality of second scan lines extending along the first direction on the substrate, wherein each of the second scan lines is connected to a column of the sub-pixels; and
a plurality of connecting holes defined on the substrate, wherein each of the second scan lines is connected to one of the first scan lines by one of the connecting holes in a non-effective display area, and the non-effective display area is between the sub-pixels.

In the array substrate of the present disclosure, the substrate further comprises:
a plurality of second scan lines extending along the first direction on the substrate, wherein each of the second scan lines is connected to a column of the sub-pixels; and
a plurality of connecting holes defined on the substrate, wherein each of the second scan lines is connected to one of the first scan lines by one of the connecting holes in a non-effective display area, and the non-effective display area is between the sub-pixels.

In the array substrate of the present disclosure, the array substrate comprises:
a first metal layer disposed on the substrate, wherein the second scan lines and a first common electrode are disposed on a same layer in the first metal layer; and
a second metal layer disposed on the first metal layer, wherein the first scan lines, the first data lines, and the second data lines are disposed on a same layer in the second metal layer.

In the array substrate of the present disclosure, the array substrate comprises:
a light filter layer disposed on the second metal layer; and
an organic planarization layer disposed on the light filter layer, wherein the pixel electrode is disposed on the organic planarization layer.

In the array substrate of the present disclosure, the substrate further comprises:
a plurality of second scan lines extending along the second direction on the substrate, wherein each of the second scan lines is connected to one column of the sub-pixels.

In the array substrate of the present disclosure, each of the sub-pixels comprises:
a second stem electrode disposed along the second direction, wherein the sub-pixels are divided into a plurality of domains by the first stem electrode and the second stem electrode.

In the array substrate of the present disclosure, the pixel electrode comprises:
a plurality of branch electrodes, wherein the branch electrodes crisscross the first stem electrode and the second stem electrode.

In the array substrate of the present disclosure, the array substrate further comprises:
a plurality of thin-film transistors (TFTs) disposed on the substrate in an array manner, wherein each of the TFTs comprises a drain, and the drain is connected to the pixel electrode.

In a second aspect, the present disclosure provides a display panel, comprising an array substrate, wherein the array substrate comprises a substrate;
a plurality of sub-pixels are arranged in an array manner on the substrate, each of the sub-pixels comprises a pixel electrode, and the pixel electrode comprises a first stem electrode disposed along a first direction;
a plurality of first data lines extend along the first direction on the substrate, each of the first data lines is connected to a group of the sub-pixels, and the group of the sub-pixels extends along the first direction; and
a plurality of first scan lines extend along the first direction on the substrate, an orthographic projection of one of the first scan lines overlaps with an orthographic projection of the first stem electrode on the substrate.

In the display panel provided by the present disclosure the substrate further comprises:
a plurality of second data lines extending along the first direction and spaced apart from each other along a second direction on the substrate, wherein each column of the sub-pixels is disposed between one of the first data lines and one of the second data lines which are adjacent to each other, and distances between the pixel electrode of each of the sub-pixels and two of the first data lines adjacent to the pixel electrode of each of the sub-pixels are equal, and the first direction and the second direction crisscross each other.

In the display panel provided by the present disclosure, the substrate further comprises:
a plurality of second scan lines extending along the first direction on the substrate, wherein each of the second scan lines is connected to a column of the sub-pixels; and
a plurality of connecting holes defined on the substrate, wherein each of the second scan lines is connected to one of the first scan lines by one of the connecting holes in a non-effective display area, and the non-effective display area is between the sub-pixels.

In the display panel provided by the present disclosure, the array substrate comprises:
a first metal layer disposed on the substrate, wherein the second scan lines and a first common electrode are disposed on a same layer in the first metal layer; and
a second metal layer disposed on the first metal layer, wherein the first scan lines, the first data lines, and the second data lines are disposed on a same layer in the second metal layer.

In the display panel provided by the present disclosure, the array substrate comprises:
a light filter layer disposed on the second metal layer; and
an organic planarization layer disposed on the light filter layer, wherein the pixel electrode is disposed on the organic planarization layer.

In the display panel provided by the present disclosure, the substrate further comprises:
a plurality of second scan lines extending along the second direction, wherein each of the second scan lines is connected to one column of the sub-pixels.

In the display panel provided by the present disclosure, each of the sub-pixels comprises:
a second stem electrode disposed along the second direction, wherein the sub-pixels are divided into a plurality of domains by the first stem electrode and the second stem electrode.

In the display panel provided by the present disclosure, the pixel electrode comprises:
a plurality of branch electrodes, wherein the branch electrodes crisscross the first stem electrode and the second stem electrode.

In the display panel provided by the present disclosure, the array substrate further comprises:
a plurality of thin-film transistors (TFTs) disposed on the substrate in an array manner, and each of the TFTs comprises a drain, and the drain is connected to the pixel electrode.

In a third aspect, the present disclosure provides a method of manufacturing the array substrate of claim 1, comprising following steps:
providing a substrate;
forming a plurality of first data lines and a plurality of scan lines extending along a first direction on the substrate; and
forming a plurality of sub-pixels arranged in an array manner on the substrate, wherein each of the sub-pixels is provided with a pixel electrode, the pixel electrode is provided with a first stem electrode extending along the first direction, and an orthographic projection of one of the scan lines overlaps with an orthographic projection of the first stem electrode on the substrate.

### Beneficial Effects of Invention

Beneficial Effect

Regarding the beneficial effects: in a plurality of sub-pixels arranged in an array manner, an orthographic projection of a first scan line, which is disposed in a same direction with a data line, disposed along a first direction overlaps with an orthographic projection of a first stem electrode extending along the first direction in a pixel electrode. By making the first stem electrode disposed along the first direction overlap with the first scan line disposed along the first direction, design space for the pixel electrode can be saved. Therefore, a pixel aperture ratio of an array substrate can be increased, light loss can be reduced, and transmittance of the array substrate can be effectively improved.

### BRIEF DESCRIPTION OF DRAWINGS

Description of Drawings

Technical solutions and beneficial effects of the present disclosure are illustrated below in detail in conjunction with drawings and specific embodiments.

FIG. 1 is a structural schematic view showing a sub-pixel of a conventional array substrate.

FIG. 2 is a structural schematic view showing an array substrate provided by an embodiment of the present disclosure.

FIG. 3 is a structural schematic view showing a cross section of the array substrate provided by the embodiment of the present disclosure.

FIG. 4 is a structural schematic view showing a cross section of a display panel provided by an embodiment of the present disclosure.

FIG. 5 is a schematic flowchart showing a method of manufacturing an array substrate provided by an embodiment of the present disclosure.

FIG. 6 is another schematic flowchart showing a method of manufacturing an array substrate provided by an embodiment of the present disclosure.

### DETAILED EMBODIMENTS OF INVENTION

Description of Invention

Hereinafter a preferred embodiment of the present disclosure will be described with reference to the accompanying drawings to exemplify the embodiments of the present disclosure can be implemented, which can fully describe the technical contents of the present disclosure to make the technical content of the present disclosure clearer and easy to understand. However, the described embodiments are only some of the embodiments of the present disclosure, but not all of the embodiments. All other embodiments obtained by those skilled in the art based on the embodiments of the present disclosure without creative efforts are within the scope of the present disclosure.

In the description of the present disclosure, it should be understood that terms such as “center”, “longitudinal”, “lateral”, “length”, “width”, “thickness”, “upper”, “lower”, “front”, “rear”, “left”, “right”, “vertical”, “horizontal”, “top”, “bottom”, “inside”, “outside”, “clockwise”, “counter-clockwise”, as well as derivative thereof should be construed to refer to the orientation as then described or as shown in the drawings under discussion. These relative terms are for convenience of description, do not require that the present disclosure be constructed or operated in a particular orientation, and shall not be construed as causing limitations to the present disclosure. In addition, terms such as “first” and “second” are used herein for purposes of description and are not intended to indicate or imply relative importance or significance. Thus, features limited by “first” and “second” are intended to indicate or imply including one or more than one these features. In the description of the present disclosure, “a plurality of” relates to two or more than two, unless otherwise specified.

In the description of the present disclosure, unless specified or limited otherwise, it should be noted that, a structure in which a first feature is “on” or “beneath” a second feature may include an embodiment in which the first feature directly contacts the second feature and may also include an embodiment in which an additional feature is formed between the first feature and the second feature so that the first feature does not directly contact the second feature. Furthermore, a first feature “on,” “above,” or “on top of” a second feature may include an embodiment in which the first feature is right “on,” “above,” or “on top of” the second feature and may also include an embodiment in which the first feature is not right “on,” “above,” or “on top of” the second feature, or just means that the first feature has a sea level elevation greater than the sea level elevation of the second feature. While first feature “beneath,” “below,” or “on bottom of” a second feature may include an embodiment in which the first feature is right “beneath,” “below,” or “on bottom of” the second feature and may also include an embodiment in which the first feature is not right “beneath,” “below,” or “on bottom of” the second feature, or just means that the first feature has a sea level elevation less than the sea level elevation of the second feature.

The disclosure below provides many different embodiments or examples for realizing different structures of the present disclosure. In order to simplify the disclosure of the present disclosure, components and settings of specific examples are described below. Of course, they are only examples and are not intended to limit the present disclosure. Furthermore, reference numbers and/or letters may be repeated in different examples of the present disclosure. Such repetitions are for simplification and clearness, which per se do not indicate the relations of the discussed embodiments and/or settings. Moreover, the present disclosure provides examples of various specific processes and materials, but the applicability of other processes and/or application of other materials may be appreciated by a person skilled in the art.

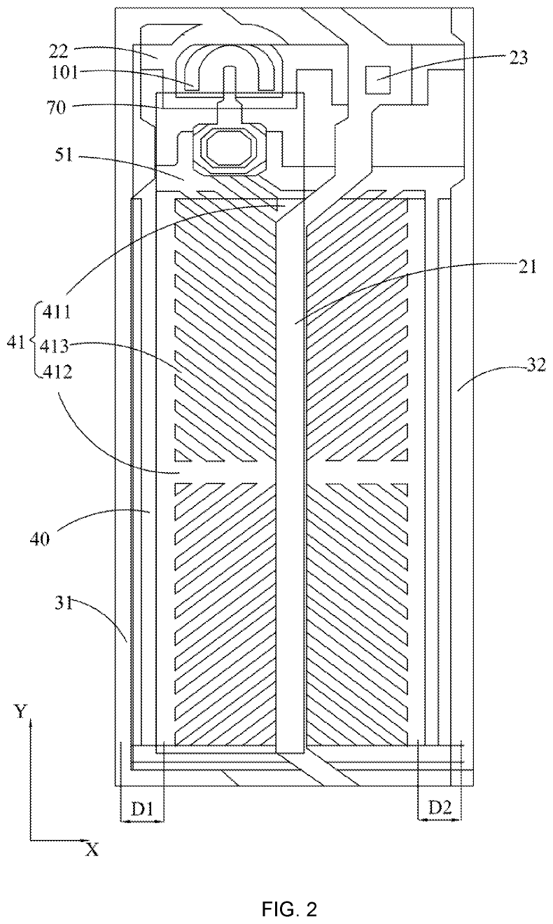

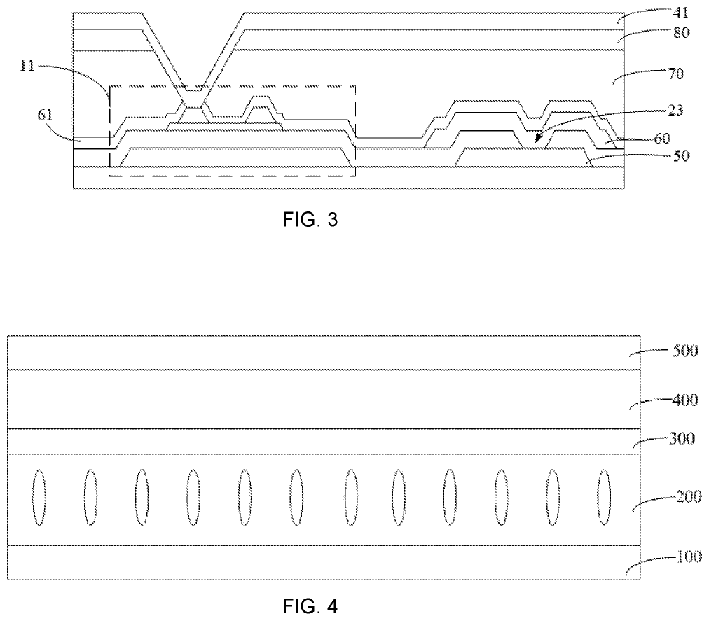

Please refer to FIGS. 2 to 3. An embodiment of the present disclosure provides an array substrate including a substrate 10. A plurality of sub-pixels 40, a plurality of first scan lines 21, and a plurality of first data lines 31 are disposed on the substrate 10.

The sub-pixels 40 are arranged in an array manner. Each of the sub-pixels 40 includes a pixel electrode 41. The pixel electrode 41 includes a first stem electrode 411 disposed along a first direction Y. Wherein, the first stem electrode is configured to divide the sub-pixels into a plurality of sub-pixel areas. Any one sub-pixel area can be provided with a plurality of branch electrodes. In the present embodiment of the present disclosure, the first direction Y is a vertical direction, and the first stem electrode is a vertical stem electrode configured to divide the sub-pixels into a two-domain pixel.

The plurality of first data lines 31 are disposed along the first direction Y. Each of the first data lines is connected to a group of the sub-pixels 40 respectively. Each of the sub-pixels 40 is disposed along the first direction Y. The plurality of first scan lines 21 are disposed along the first direction Y. An orthographic projection of the first scan lines 21 overlaps with an orthographic projection of the first stem electrode 411 on the substrate 10. In the present embodiment of the present disclosure, the first scan lines 21 are vertical scan lines.

In the array substrate of the present embodiment of the present disclosure, in the plurality of sub-pixels arranged in an array manner, an orthographic projection of a first scan line, which is disposed in a same direction with the first data line, disposed along a first direction overlaps with an orthographic projection of the first stem electrode extending along the first direction in a pixel electrode. By making the first stem electrode disposed along the first direction overlap with the first scan line disposed along the first direction, a design space of the pixel electrode can be saved. Therefore, a pixel aperture ratio of an array substrate can be increased, light loss can be reduced, and transmittance of the array substrate can be effectively improved. In addition, compared with HG2D designs, which needs to design a shielding electrode to shield a vertical scan line signal to prevent a data line from being affected by the vertical scan line signal, the array substrate provided by the present disclosure can omit the shielding electrode. Therefore, a usage of photomask can be reduced, manufacturing processes can be simplified, and production cost can be reduced.

In some embodiments, a plurality of second scan lines 22 are further disposed on the substrate 10. The second scan lines extend along a second direction X. Wherein, the second direction X crosses the first direction Y. For example, in the present embodiment of the present disclosure, the second direction X is perpendicular to the first direction Y. Wherein, the second direction X is horizontal. That is, the first scan lines 21 are horizontal scan lines.

Each of the second scan lines 22 is connected to one column of the sub-pixels. Each of the first scan lines 21 is connected to one of the second scan lines. The first scan lines 21 are configured to provide a driving signal to the second scan lines 22.

In some embodiments, a plurality of connecting holes 23 are further defined on the substrate 10. The second scan lines 22 are connected to the first scan lines 21 by the connecting holes 23 in a non-effective display area which is between the sub-pixels 40. Specifically, the non-effective display area is a black matrix area between the sub-pixels 40. Specifically, the first scan lines are horizontal scan lines which are perpendicular to the second scan lines.

In some embodiments, as shown in FIG. 2, the plurality of first data lines 31 are evenly spaced apart from each other in the second direction X. Each column of the sub-pixels 40 is disposed between two of the first data lines 31 adjacent to the sub-pixels. Distances between the pixel electrode 41 of each of the sub-pixels and two of the first data lines 31 adjacent to the pixel electrode of the sub-pixels are equal. The first direction Y crosses the second direction X. Data lines adjacent to the sub-pixels 40 are second data lines 32. The second data lines 32 extend along the first direction Y. Distances between each column of the sub-pixels 40 and two of the first data lines 31 adjacent to each column of the sub-pixels are equal. That is, each of the sub-pixels is disposed at a middle between one of the data lines 31 and one of the second data lines 32. Wherein, a first distance D1 is equal to a second distance D2. Specifically, the first distance D1 is a distance between the pixel electrodes 41 of the sub-pixels and the first data lines 31 connected to the pixel electrodes. The second distance D2 is a distance between the pixel electrodes 41 of the sub-pixels and the second data lines 32 connected to the pixel electrodes. If distances between the pixel electrodes and two data lines adjacent to the pixel electrodes are different, capacitive coupling effects would be different, contributing to a vertical crosstalk generated between the sub-pixels. Therefore, by making the first distance D1 equal to the second distance D2, the distances between the pixel electrodes 41 and the two data lines (the first data lines 31 and the second data lines 32) at two sides of the sub-pixels 40 can be prevented from being different. As such, the vertical crosstalk generated from the different capacitive coupling effects can be prevented.

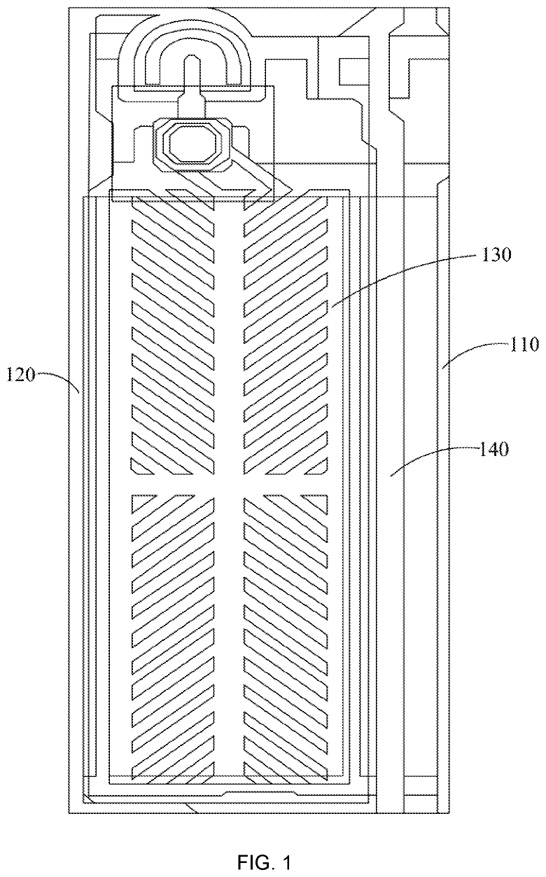

In some embodiments, as shown in FIG. 3, The array substrate further comprises a plurality of thin-film transistors (TFTs) 11. The TFTs are disposed on the substrate 10 in an array manner. The TFTs 11 include a drain 101. As shown in FIG. 1, the drain 101 is connected to the pixel electrode 41. For example, the TFTs commonly include three electrodes, namely a gate, a source, and a drain. Wherein, the gate is disposed in a first metal layer 50, and the source and the drain are disposed in a second metal layer 60. The source and the drain in the TFTs can be interchangeable in terms of functions according to requirements.

In some embodiments, the sub-pixel 40 further includes a second stem electrode 412. The second stem electrode 412 is disposed along the second direction X. The sub-pixel 40 is divided into multiple domains by the first stem electrode 411 and the second stem electrode 412. As shown in FIG. 2, the sub-pixel 40 is divided into four domains symmetrical to each other by the first stem electrode 411 and the second stem electrode 412. Liquid crystals of the domains can compensate each other, thereby improving optical performance of liquid crystal array substrates in wide viewing angles.

In some embodiments, the pixel electrode 41 further includes a plurality of branch electrodes 413. The branch electrodes 413 crisscross the first stem electrode 411 and the second stem electrode 412, respectively. Specifically, the branch electrodes 413 in a single domain are parallel to each other and are spaced apart from each other. Extending directions of the branch electrodes 412 in two adjacent domains are different. For example, the branch electrodes extend in an angle of 45°, 135°, −135°, or −45° with respect to the second stem electrode.

In some embodiments, as shown in FIG. 2, the array substrate further includes:
the first metal layer 50 and the second metal layer 60. The first metal layer 50 is disposed on the substrate 10. The first scan lines 21 and a first common electrode are disposed on a same layer in the first metal layer 50. Wherein, the first common electrode is configured to store a capacitor. By patterning the first scan lines 21 and the first common electrode with a same material in a same process, the manufacturing processes can be simplified and the production cost can be reduced.

The second metal layer 60 is disposed on the first metal layer 50. The second scan lines 22, the first data lines 31, and the second data lines 32 are disposed on a same layer in the second metal layer 60. By patterning the second scan lines 22, the first data lines 31, and the second data lines 32 with a same material in a same process, the manufacturing processes can be further simplified and the production cost can be reduced.

In some embodiments, the array substrate further includes a first insulating layer 51. The first insulating layer 51 is disposed between the first metal layer 50 and the second metal layer 60. The connecting holes 23 are defined on the first insulating layer 51 and penetrate the first insulating layer 51. The first scan lines 21 in the first metal layer 50 are connected to the second scan lines 22 in the second metal layer 60 by the connecting holes 23.

The array substrate further comprises a light filter layer 70 disposed on the second metal layer 60. It can be understood that a passivation (PV) layer can be further disposed between the light filter layer and the second metal layer. The light filter layer 70 includes a filter plate having a planar structure. In each of the sub-pixels, an orthographic projection of the filter plate on the substrate overlaps with at least part of an orthographic projection of each of the pixel electrodes on the substrate. Wherein, the filter plate can be one of a red filter plate, a blue filter plate, or a green filter plate. Color of the filter plate is same as color of the sub-pixels. The plurality of sub-pixels constitute a pixel. For example, each sub-pixel (pixel) can include three sub-pixels, namely a red sub-pixel R, a green sub-pixel G, and a blue sub-pixel B. Alternatively, each of the sub-pixels can also include four sub-pixels, namely the red sub-pixel, the green sub-pixel, the blue sub-pixel, and a white sub-pixel, which is not limited by the present embodiment.

In some embodiments, the array substrate further includes an organic planarization layer 80 which is a polymer film on array. The organic planarization layer 80 is disposed on the light filter layer 70. The organic planarization layer 80 has an insulating function. Wherein, the pixel electrode is disposed on the organic planarization layer 80.

To better implement the array substrate of the present disclosure, an embodiment of the present disclosure further provides a display panel including the array substrate. The display panel may be a liquid crystal display (LCD) panel. For example, as shown in FIG. 4, the display panel includes the array substrate 100, a liquid crystal layer 200, a first electrode 300, a black matrix layer 400, and a cover glass 500, which are sequentially stacked. Wherein, the first electrode 300 is an indium tin oxide (ITO) common electrode. When an electric field between the pixel electrode and the common electrode is changed, the liquid crystal layer 200 is deflected by an electric field force, thereby realizing a display function of a panel. Because the display panel includes an above array substrate, the display panel includes same beneficial effects of the above array substrate which are not described again here.

The present disclosure further provides a display device including the display panel. Because the display device includes an above display panel, the display device includes same beneficial effects of the above display panel which are not described again here.

Applications of the display device of the present embodiment are not limited and can be televisions, notebooks, tablets, wearable display devices such as smart wristbands and smart watches, cell phones, virtual reality equipment, augmented reality equipment, vehicle displays, advertising light boxes, or any products or components having a display function.

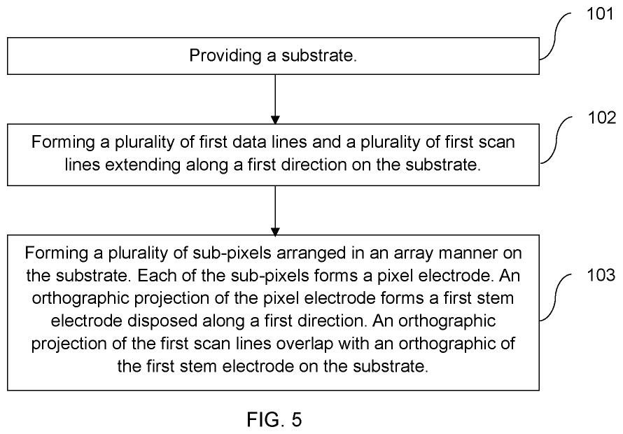

To better implement the array substrate of the present disclosure, an embodiment of the present disclosure further provides a manufacturing method of the array substrate. As shown in FIG. 5, the manufacturing method includes following steps S101 to S103:

S101, providing a substrate.

Wherein, the substrate 10 may be a rigid substrate such as a glass substrate or a polymethyl methacrylate (PMMA) substrate. The substrate 10 may also be a flexible substrate such as a polyethylene terephthalate (PET) substrate or a polyimide (PI) substrate.

S102, forming a plurality of first data lines and a plurality of first scan lines extending along a first direction on the substrate.

Specifically, the first data lines and the first scan lines may be made of a metal layer 50 and may be disposed on a same layer. The first metal layer 50 is deposited on the substrate 10. By forming the first data lines and the first scan lines on the same layer, manufacturing processes can be simplified.

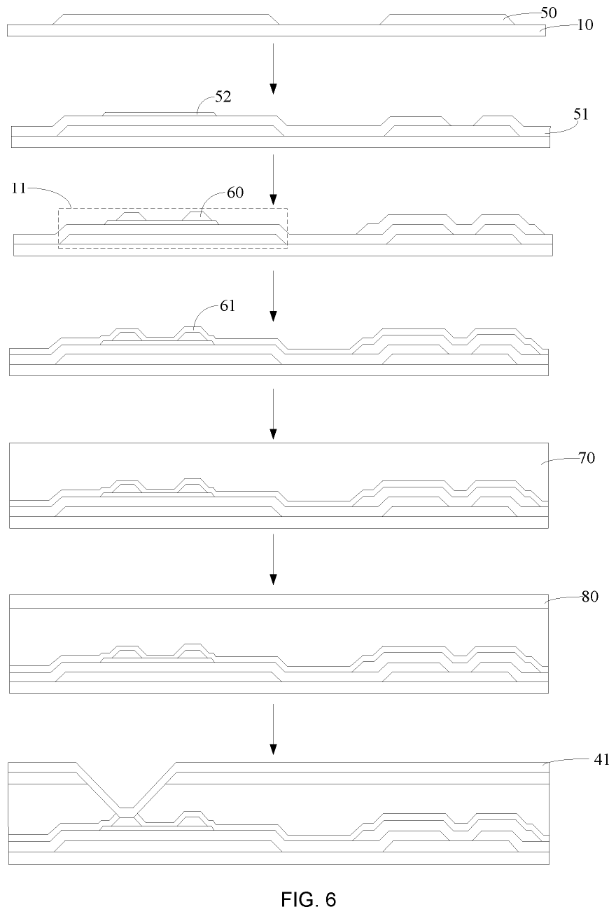

For example, as shown in FIG. 6, after the step S102, the method may further include:

Step 1), depositing a first insulating layer 51 covering the first metal layer 50, and forming a plurality of connecting holes 23 on positions corresponding to the first scan lines, wherein part of the first metal layer may further be a gate of a plurality of thin-film transistor (TFTs) 11.

Step 2): depositing a semiconductor layer 52 on the first insulating layer 51.

step 3): depositing a second metal layer 60 on the semiconductor layer 52.

step 4): depositing and etching the second metal layer 60 on the semiconductor layer 52, wherein part of the second metal layer is a source and a drain of the TFTs 11, a plurality of second data lines, and a plurality of second scan lines. Part of the second metal layer corresponding to the second scan lines is connected to the first scan lines by the connecting holes.

step 5): depositing a passivation layer 61 covering the second metal layer 60, wherein the passivation layer 61 has an insulating function.

step 6): depositing a light filter layer 70 covering the passivation layer 61.

step 7): depositing an organic planarization layer 80 covering the light filter layer 70.

S103, forming a plurality of sub-pixels arranged in an array manner on the substrate. Each of the sub-pixels includes a pixel electrode. The pixel electrode includes a first stem electrode disposed along a first direction. An orthographic projection of the first scan lines overlaps with an orthographic projection of the first stem electrode on the substrate. Specifically, as shown in FIG. 6, a pixel electrode 41 is disposed on the first metal layer 50 and is deposited on the organic planarization layer 80.

In the above embodiments, the focus of each embodiment is different, and for a part that is not detailed in an embodiment, reference may be made to related descriptions of other embodiments.

An array substrate, a manufacturing method thereof, and a display panel have been described in detail with embodiments provided by the present disclosure which illustrates principles and implementations thereof. However, the description of the above embodiments is only for helping to understand the technical solution of the present disclosure and core ideas thereof, and it is understood by those skilled in the art that many changes and modifications to the described embodiment can be carried out without departing from the scope and the spirit of the disclosure that is intended to be limited only by the appended claims.

What is claimed is:

1. An array substrate, comprising a substrate, wherein the substrate is configured with:
a plurality of sub-pixels arranged in an array manner, each of the sub-pixels comprising a pixel electrode, the pixel electrode comprising a first stem electrode disposed along a first direction;
a plurality of first data lines extending along the first direction, each of the first data lines connected to a group of the sub-pixels, the group of the sub-pixels extending along the first direction; and
a plurality of first scan lines extending along the first direction, wherein an orthographic projection of one of the first scan lines overlaps with an orthographic projection of the first stem electrode on the substrate.

2. The array substrate of claim 1, wherein a plurality of second data lines extend along the first direction and are spaced apart from each other along a second direction on the substrate, each column of the sub-pixels is disposed between one of the first data lines and one of the second data lines which are adjacent to each other, distances between the pixel electrode of each of the sub-pixels and two of the first data lines adjacent to the pixel electrode of each of the sub-pixels are equal, and the first direction and the second direction cross each other.

3. The array substrate of claim 1, wherein a plurality of second scan lines extend along the first direction on the substrate, and each of the second scan lines is connected to a column of the sub-pixels; and
a plurality of connecting holes are defined on the substrate, each of the second scan lines is connected to each of the first scan lines by one of the connecting holes in a non-effective display area, and the non-effective display area is an area between the sub-pixels.

4. The array substrate of claim 2, wherein a plurality of second scan lines extend along the first direction on the substrate, and each of the second scan lines is connected to a column of the sub-pixels; and
a plurality of connecting holes are defined on the substrate, each of the second scan lines is connected to each of the first scan lines by one of the connecting holes in a non-effective display area, and the non-effective display area is an area between the sub-pixels.

5. The array substrate of claim 4, wherein the array substrate comprises:
a first metal layer disposed on the substrate, wherein the second scan lines and a first common electrode are disposed on a same layer in the first metal layer; and
a second metal layer disposed on the first metal layer, wherein the first scan lines, the first data lines, and the second data lines are disposed on a same layer in the second metal layer.

6. The array substrate of claim 5, wherein the array substrate comprises:
a light filter layer disposed on the second metal layer; and
an organic planarization layer disposed on the light filter layer, wherein the pixel electrode is disposed on the organic planarization layer.

7. The array substrate of claim 2, wherein a plurality of second scan lines extend along the second direction on the substrate, and each of the second scan lines is connected to one column of the sub-pixels.

8. The array substrate of claim 6, wherein each of the sub-pixels comprises:
a second stem electrode disposed along the second direction, wherein the sub-pixels are divided into a plurality of domains by the first stem electrode and the second stem electrode.

9. The array substrate of claim 7, wherein the pixel electrode comprises:
a plurality of branch electrodes, wherein the branch electrodes crisscross the first stem electrode and the second stem electrode.

10. The array substrate of claim 1, wherein the array substrate comprises a plurality of thin-film transistors (TFTs) disposed on the substrate in an array manner, and each of the TFTs comprises a drain, and the drain is connected to the pixel electrode.

11. A display panel, comprising an array substrate, wherein the array substrate comprises a substrate, and the substrate is configured with:
a plurality of sub-pixels arranged in an array manner, each of the sub-pixels comprising a pixel electrode, the pixel electrode comprising a first stem electrode disposed along a first direction;
a plurality of first data lines extending along the first direction, each of the first data lines connected to a group of the sub-pixels, the group of the sub-pixels extending along the first direction; and
a plurality of first scan lines extending along the first direction, wherein an orthographic projection of one of the first scan lines overlaps with an orthographic projection of the first stem electrode on the substrate.

12. The display panel of claim 11, wherein a plurality of second data lines extend along the first direction and are spaced apart from each other along a second direction on the substrate, each column of the sub-pixels is disposed between one of the first data lines and one of the second data lines which are adjacent to each other, distances between the pixel electrode of each of the sub-pixels and two of the first data lines adjacent to the pixel electrode of each of the sub-pixels are equal, and the first direction and the second direction cross each other.

13. The display panel of claim 12, wherein a plurality of second scan lines extend along the first direction on the substrate, each of the second scan lines is connected to a column of the sub-pixels; and
a plurality of connecting holes are defined on the substrate, each of the second scan lines is connected to each of the first scan lines by one of the connecting holes in a non-effective display area, and the non-effective display area is an area between the sub-pixels.

14. The display panel of claim 13, wherein the array substrate comprises:
a first metal layer disposed on the substrate, wherein the second scan lines and a first common electrode are disposed on a same layer in the first metal layer; and
a second metal layer disposed on the first metal layer, wherein the first scan lines, the first data lines, and the second data lines are disposed on a same layer in the second metal layer.

15. The display panel of claim 14, wherein the array substrate comprises:
a light filter layer disposed on the second metal layer; and
an organic planarization layer disposed on the light filter layer, wherein the pixel electrode is disposed on the organic planarization layer.

16. The display panel of claim 12, wherein a plurality of second scan lines extend along the second direction on the substrate, and each of the second scan lines is connected to one column of the sub-pixels.

17. The display panel of claim 16, wherein each of the sub-pixels comprises:
a second stem electrode disposed along the second direction, wherein the sub-pixels are divided into a plurality of domains by the first stem electrode and the second stem electrode.

18. The display panel of claim 17, wherein the pixel electrode comprises:
a plurality of branch electrodes, wherein the branch electrodes crisscross the first stem electrode and the second stem electrode.

19. The display panel of claim 11, wherein the array substrate comprises a plurality of thin-film transistors (TFTs) disposed on the substrate in an array manner, and each of the TFTs comprises a drain, and the drain is connected to the pixel electrode.

20. A method of manufacturing the array substrate of claim 1, comprising following steps:
providing a substrate;
forming a plurality of first data lines and a plurality of first scan lines extending along a first direction on the substrate; and
forming a plurality of sub-pixels arranged in an array manner on the substrate, wherein each of the sub-pixels is provided with a pixel electrode, the pixel electrode is provided with a first stem electrode extending along the first direction, and an orthographic projection of one of the first scan lines overlaps with an orthographic projection of the first stem electrode on the substrate.
